(19) United States
(12) Patent Application Publication
(10) Pub. No.: US 2026/0341340 A1
(43) Pub. Date: Oct. 29, 2026

(54) MEMORY DEVICE WITH EXTENDED WRITE DATA WINDOW

(71) Applicant: Rambus Inc., San Jose, CA (US)

(72) Inventors: Christopher Haywood, Fernandina Beach, FL (US); Michael Raymond Miller, Raleigh, NC (US)

(21) Appl. No.: 19/106,325

(22) PCT Filed: Aug. 23, 2023
(86) PCT No.: PCT/US2023/072741

§ 371 Date: Feb. 25, 2025

Related U.S. Application Data
(60) Provisional application No. 63/374,419, filed on Sep. 2, 2022.

(51) Int. Cl. G11C 11/4096; G11C 11/4076; G11C 11/4093

(52) U.S. Cl. CPC G11C 11/4096; G11C 11/4076; G11C 11/4093

(57) ABSTRACT

A memory device enables write operations with an extended write data window. In a first type of write operation, the memory device receives a merged row/column command at an input interface. The memory device initiates a row operation (e.g., a row activation) of a memory array and subsequently internally initiates a column operation (e.g., a write command) with timing controlled by internal logic. The write data may be received before, during, or after the write command. In another type of write operation, the memory device receives a write-activate command for initiating a row operation of the memory array that includes one or more control bits indicating that a write command will follow. The memory device subsequently receives the write command at the input interface and initiates the write operation. The write data may be received during an extended write data window before or after the write command.

### BACKGROUND

Memory devices such as Dynamic Random-Access Memory (DRAM) typically include an array of memory cells and supporting logic circuitry for facilitating memory operations. Traditional memory devices include a bidirectional data port that can introduce a bottleneck for certain sequences of read and write operations.

### BRIEF DESCRIPTION OF THE DRAWINGS

The teachings of the embodiments herein can be readily understood by considering the following detailed description in conjunction with the accompanying drawings.

FIG. 1 is a block diagram illustrating an example embodiment of a memory device.

FIG. 2A is an example timing diagram associated with a memory device executing activate and write commands.

FIG. 2B is an example timing diagram associated with a memory device executing write-activate and write commands.

FIG. 2C is an example timing diagram associated with a memory device executing a write-row/column command.

FIG. 3 is a block diagram illustrating an example embodiment of write logic associated with a memory device.

FIG. 4 is a chart illustrating an example encoding scheme for write-activate and read-activate commands.

FIG. 5 is a chart illustrating a first example encoding scheme for write-row/column command and read-row/column command.

FIG. 6 is a chart illustrating a second example encoding scheme for write-row/column command and read-row/column command.

FIG. 7 is a chart illustrating a set of example configurations of a memory device in various embodiments.

FIG. 8 is a block diagram illustrating an example embodiment of a memory module.

### DETAILED DESCRIPTION

A memory device enables write operations in which write data may be received in an extended write data window before and/or after a write command. In a first type of write operation, an input interface of the memory device receives a merged row/column command. The memory device initiates a row operation (e.g., a row activation) of a memory array upon receiving the merged row/column command and the memory device subsequently internally initiates a column operation (e.g., a write command) with timing controlled by internal scheduling logic. The write data may be received at the external interface of the memory device before, during, or after the memory device internally initiates the write command. The memory device may similarly facilitate read operations using a merged row/column command in which the memory device initiates a row operation (e.g., a row activation) and subsequently internally initiates a read command with timing controlled by internal logic.

In another type of write operation, the memory device receives a write-activate command at the input interface for initiating a row operation of the memory array that includes one or more control bits indicating that a write command will follow. The memory device subsequently receives a write command at the input interface and initiates the write operation upon receiving the write command. The write data may be received at the input interface during write data windows before or after the write command. The memory device may similarly facilitate read operations using a read-activate command that includes one or more control bits indicating that a read command will follow. The memory device then initiates the read operation upon receiving the read command at the input interface.

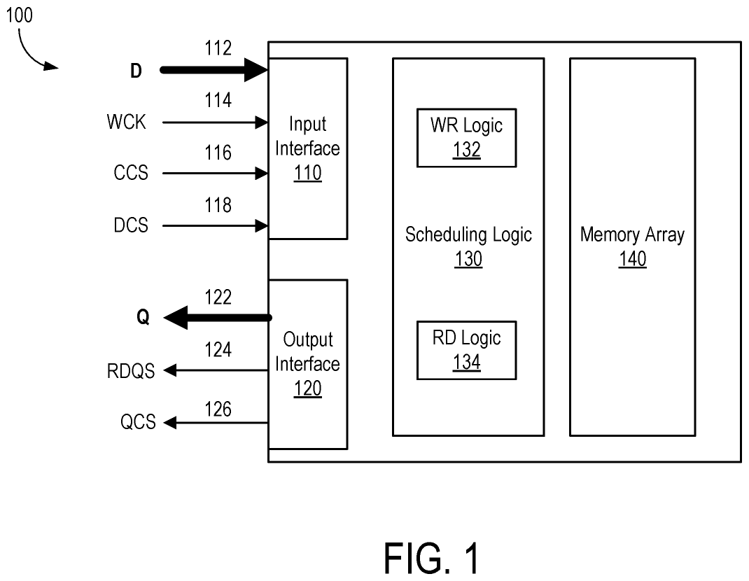

FIG. 1 is an example embodiment of a memory device 100. The memory device 100 includes an input interface 110, an output interface 120, scheduling logic 130 including write logic 132 and read logic 134, and a memory array 140.

The memory array 140 comprises an array of memory cells (e.g., DRAM (dynamic random-access memory) cells). The memory array 140 may be arranged in one or more memory banks that each comprise a set of memory cells arranged in rows and columns. The banks may be organized in bank groups. A memory address of an individual memory cell may be characterized by a package and/or chip identifier that identifies the memory device 100, a bank group, a bank address, a row address, and a column address. To execute a read or write operation associated with a particular memory address, the memory array 140 first performs a row operation to activate a row of a memory bank (e.g., by executing an activate command) and then performs a column operation to read or write from the address. In a write operation, the memory array 140 receives write data following the write command and writes it to the specified memory location. In a read operation, the memory array 140 outputs data from the specified memory address. The memory array 140 may furthermore perform other operations responsive to received commands such as refresh operations, precharge operations, mode register read and write operations, and other memory operations.

The memory array 140 may operate with various timing constraints associated with different types of memory operations. For example, a read/write timing constraint may enforce a minimum time in between a row of the memory array 140 being activated and the memory array 140 performing a read or write operation associated with that row. Furthermore, the memory array 140 may be constrained to having a single row per bank activated at a given time. In another example, a timing constraint may enforce a minimum time between the memory array 140 writing data to a memory location and the memory array 140 reading the data from that memory location. Other timing requirement may be imposed based on the specifications of the memory array 140.

The input interface 110 receives input commands and/or data via a set of input ports including a command/data port (D) 112, a write clock port (WCK) 114, a command enable port (CCS) 116, and a data enable port (DCS) 118. The D port 112 may comprise a multi-bit port (e.g., 8 bits, 10 bits, 12 bits, or a different number of bits) for receiving memory device commands and write data for writing to the memory array 140. The WCK port 114 receives a timing reference (e.g., a single-ended or differential clock signal) associated with commands and data received on the D port 112. In an embodiment, the same set of pins of the D port 112 may be used to send either data or commands. Alternatively, the D port 112 may include a set of dedicated data pins and a separate set of dedicated command pins. The CCS port 116 and DCS port 118 receive respective enable signals to indicate whether the D port 112 is receiving a command or write data. For examples, when the D port 112 is receiving a command, the command enable signal on the CCS port is asserted and the data enable signal on the DCS port is unasserted. When the D port 112 is receiving write data, the command enable signal on the CCS port is unasserted and the data enable signal on the DCS port is asserted.

The output interface 120 outputs data read from the memory array 140 in response to read commands. The output interface 120 includes a data output port (Q) 122, a read clock port (RDQS) 124, and a read enable port (QCS) 126. The Q port 122 may comprise a multi-bit port (e.g., 8 bits) for outputting read data from the memory array 140 in response to a read command. The RDQS port 124 outputs a timing reference (e.g., a single-ended or differential clock signal) associated with the read data outputted on the Q port 122. The QCS port 126 outputs a read data enable signal that is asserted when data is being transmitted on the Q port 122 and is otherwise unasserted.

In an embodiment the input interface 110 and the output interface 120 are each unidirectional. The input interface 110 and output interface 120 may operate concurrently such that, for example, the input interface 110 receives commands or write data concurrently with the output interface 120 outputting read data.

The scheduling logic 130 decodes the commands received at the input interface 110, controls timing of internal commands issued to the memory array 140, and controls timing of sending data between the memory array 140 and the interfaces 110, 120. The scheduling logic 130 includes write logic 132 for facilitating write operations of the memory array 140 and read logic 134 for facilitating read operations. In an embodiment, some internal logic may be shared between the write logic 132 and read logic 134. Furthermore, the scheduling logic 130 may include additional logic (not shown) for facilitating other types of commands such as refresh, precharge, or mode register operations.

As explained in further detail below, the commands received at the input interface 110 may include higher level commands than the commands internally issued by the scheduling logic 130 to the memory array 140. For example, in response to receiving a single command at the input interface 110, the scheduling logic 130 may issue multiple internal commands to the memory array 140 scheduled to meet the timing constraints of the memory array 140. Furthermore, in some instances, the scheduling logic 130 may schedule transmission of write data or commands to the memory array 140 in a different order than received at the input interface 110.

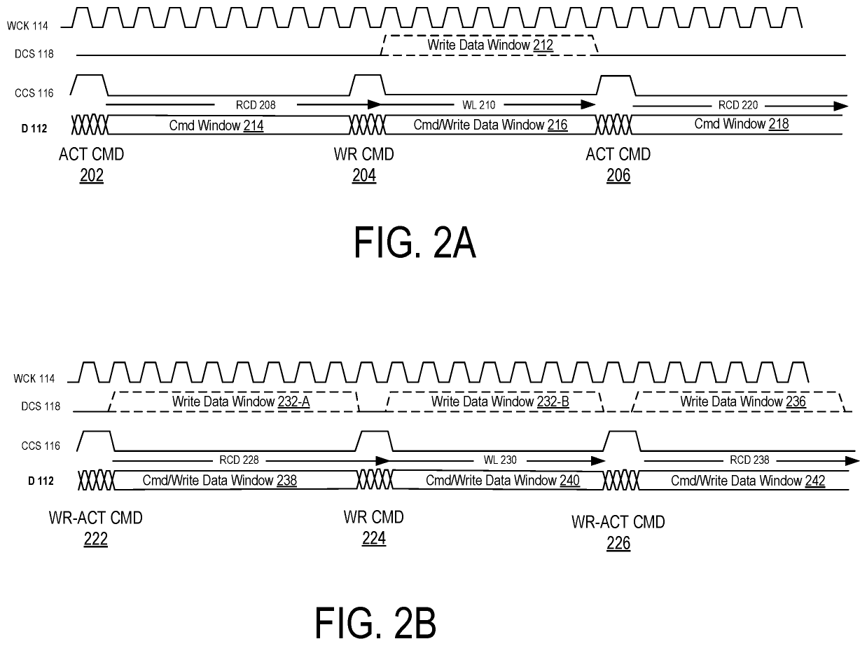

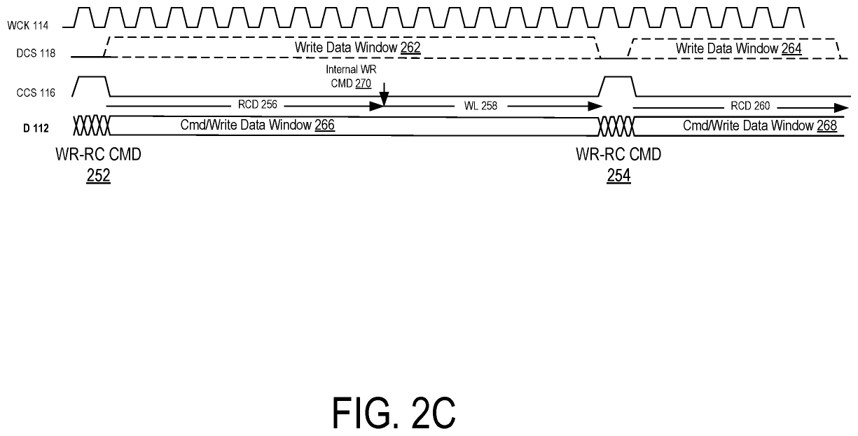

FIG. 2.A-C are example timing diagrams associated with write operations of the memory device 100 described above.

In the example of FIG. 2A, the memory device 100 receives an activate command 202 at the input interface 110, which causes the memory device 100 to perform a row operation activating one or more rows specified in the activate command 202. After at least a delay time (RCD) 208, the memory device 100 receives a write command 204 at the input interface 110 (where the RCD time 208 represents a minimum time between opening a row via an activate command and accessing a column).. A write data window 212 opens after the write command 204 is received and closes after a write latency (WL) time 210. The memory device 100 may receive the write data associated with the write command 204 anytime during this write data window 212. Upon receiving the write data, the memory device 100 performs a column operation to write the data to the specified columns of the activated row(s). In this example, another activate command 206 is received after the WL time 210, which starts a new RCD time 220.

In this example, the memory device 100 can optionally receive other commands during the command windows 214, 218 and may receive either commands or data during the command/write window 216. For example, the memory device 100 could receive commands associated with other memory banks on the D port 112 during these windows 214, 216, 218 and/or commands associated with other types of memory operations. The scheduling logic 130 controls timing of issuing the received commands and write data to the memory array 140 to ensure compliance with relevant timing constraints.

While FIG. 2A illustrates timing associated with a write operation, the memory device 100 may similarly facilitate read operations. For example, the memory device 100 may receive an activate command on the D port 112 (activating a row) followed by a read command (specifying columns of the activated row to read from). The memory device 100 outputs the read data to the Q port 122 following the read command.

In the example of FIG. 2B, the memory device 100 receives a write-activate command 222 at the input interface 110. The write-activate command 222 encodes instructions to perform an activate operation on one or more specified rows in the memory array 140 and also encodes an indication that the command 222 will be followed by a write command 224. In response to the write-activate command 222, the scheduling logic 130 issues an internal activate command to the memory array 140 to activate the specified row of the memory 140. The write command 224 is then received after the RCD time 228. The write-activate command 222 opens a write data window 232 (including write data windows 232-A, 232-B) that remains open except when other commands are being received on D port 112 (e.g., write command 224, activate command 226, or other commands sent during the command/write windows 238, 240). The memory device 100 may receive the write data associated with the write command 224 anytime during the write data windows 232. The write data window 232 includes a first write data window 232-A initiated immediately after the write-activate command 222 prior to the write command 224 being received, and a second write data window 232-B that opens after the write command 224. If write data is received during the write data window 232-A prior to receiving the write command 224, the scheduling logic 130 may buffer the write data and then issue the write data to the memory array 140 with appropriate timing after the write command 224. In various embodiments, the write data window 232 may close a fixed time after receiving the write command 224 or may close after all write data is received (which may be a variable amount of time for different operations).

As in the example of FIG. 2A, the memory device 100 can also optionally receive other commands during the command/data windows 238, 240 as long as they do not interfere with the write operation (e.g., commands associated with other memory banks). In some cases, write data may be split between different parts of the write window 232-A, 232-B. For example, a portion of the write data may be received prior to the write command 224 during the write window 232-WO A and another portion of the write data may be received after the write command 224 during the write window 232-B. Furthermore, write data may be interleaved with commands in the command/write data windows 238, 240. The scheduling logic 130 controls timing of issuing the received commands and write data to the memory array 140 to ensure compliance with relevant timing constraints.

FIG. 2B also illustrates another write-activate command 226 received after the WL time 230 which triggers a new RCD period 238 associated with a subsequent write operation. The write-activate command 226 opens a new write data window 236 associated with the subsequent write-activate command 226. Alternatively, the memory device 100 can receive other commands during the command/write data window 242 associated with other banks.

In example embodiment, the memory device 100 applies the write data to write commands in the orders received. For example, write data received during the write data window 232 is associated with the write-active command 222 and write command 224 and write data received during the write data window 236 is associated with the write-activate command 226 and subsequent write command (not shown). In some embodiments, the write data windows 232, 236 may overlap (i.e., the WL time 230 may be longer than shown in FIG. 2B and the write-activate command 226 may be received prior to the end of the WL time 230). Here, the memory device 100 associates the write data received during the overlapping windows with the earliest write command that is not completed. Once all the write data associated with the earliest write operation is complete, the memory device 100 associated subsequently write data with the next received write command.

While FIG. 2B illustrates timing associated with a write-activate command, the memory device 100 may similarly facilitate read operations via a read-activate command. In this case, the memory device 100 receives a read-activate command that causes indicates it will be followed by a read command. The memory device 100 internally issues an activate command to the memory array 140 and then reads from the memory after receiving the read command. The memory device 100 outputs the read data on the Q port 122 following the read command.

In the example of FIG. 2C, the memory device 100 receives a write-row/column (WR-RC) command 252 at the input interface 110. The WR-RC command 252 encodes instructions to perform an activate operation on one or more specified rows in the memory array 140 and information for subsequently issuing a write command 270 associated with one or more specified columns. In response to the externally received WR-RC command 252, the scheduling logic 130 issues an activate command to activate the one or more specified rows in the memory array 140 and subsequently internally issues a write command 270 to the memory array 140 with appropriate timing to meet timing constraints of the memory array 140 (e.g., after the RCD time 256). Thus, the externally received WR-RC command 252 operates to initiate both a row operation (the activate command) and a column operation (the write command 270) with timing controlled internally by the memory device 100.

In this example, a write data window 262 is opened immediately after the WR-RC command 252 is received and closes after the WL time 258 following the internal write command 270. Thus, write data may be received anytime during the write data window 262 including before, during, or after the internal write command 270. If write data is received prior to the scheduling logic 140 issuing the write command 270, the scheduling logic 130 may buffer the write data and then issue the write data to the memory array 140 with appropriate timing after the write command 270 (e.g., during the WL period 258). In some cases, a portion of the write data may be received prior to the write command 270 and another portion of the write data may be received after the write command 270.

This example also shows a subsequent WR-RC command 254, which opens a new write data window 264 associated with a subsequent write operation and starts a new RCD time 260.

As described in the example of FIG. 2B, the WR-RC command 254 may occur prior to the end of the WL time 258 and thus the write data windows 262, 264 may overlap. In this case, the write data is applied in the same order as the received commands 252, 254. In various embodiments, the write data windows 262 may close a fixed time after initiating the internal write command 270 or may close after all write data is received (which may be a variable amount of time for different operations).

As in the examples of FIGS. 2A-B, the memory device 100 can also optionally receive other commands during the command/write data windows 266, 268 as long as they do not interfere with the write operation (e.g., commands associated with other memory banks). In some instances, write data may be interleaved with commands in the command/write data windows 266, 268. The scheduling logic 130 controls timing of issuing the received commands and write data to the memory array 140 to ensure compliance with relevant timing constraints.

While FIG. 2C illustrates timing associated with a WR-RC command, the memory device 100 may similarly facilitate read operations via a read-row/column (RD-RC) command. Here, the RD-RC command encodes instructions to perform an activate operation on one or more specified rows in the memory array 140 and for subsequently issuing a read command associated with one or more specified columns of the activated row. Data is output to the Q port 122 following the read command.

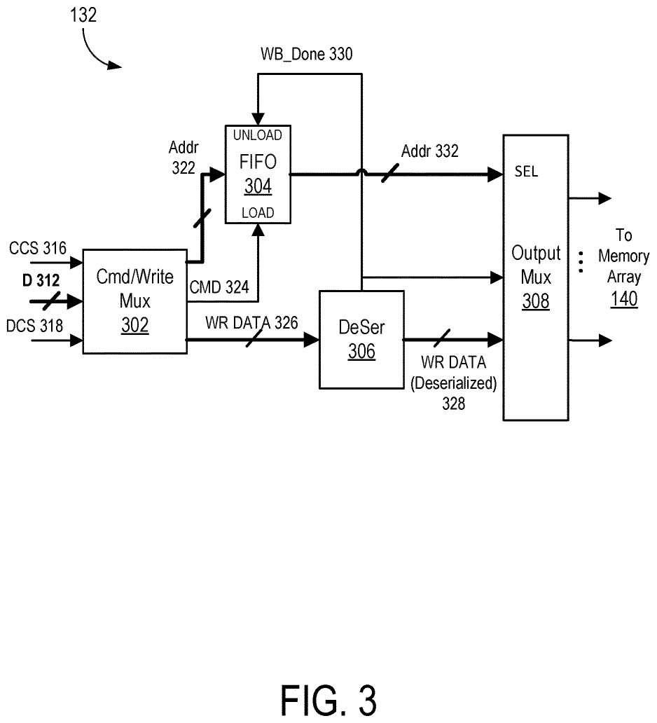

FIG. 3 is an example embodiment of an architecture for the write logic 132 of the memory device 100. The write logic 132 includes a command/write multiplexer (mux) 302, an address buffer 304 (which may comprise a first-in-first-out (FIFO)) buffer), a data deserializer (DeSer) 306, and an output multiplexer 308. The command/write multiplexer 302 receives the command enable (CCS) signal 316, D port signals 312, and data enable (DCS) signals 318 from the CCS 116, D 112, and DCS 118 ports respectively. When the CCS signal 316 is asserted and the DCS signal 318 is unasserted (indicative of the D signals 312 being a command), the command/write mux 302 outputs the D signals to the address buffer 304 as the address signal 322 and command signal 324. The command signals 324 encodes the command type (e.g., write, write-activate, write-row/column, etc.) and control the address buffer 304 to load the address 322 into the address buffer 304.

When the CCS signal 316 is unasserted and the DCS signal 318 is asserted (indicative of the D signal 312 being write data), the command/write mux 302 outputs the D signals 312 to the data deserializer 306 as the write data signals 326. The data deserializer 306 deserializes the write data 326 to produce deserialized output write data 328. For example, in one configuration, the data deserializer 306 receives 8-bit inputs via the write data lines 326 that are deserialized to 128-bit outputs on the deserialized write data lines 328. When the data deserializer 306 is ready to output (e.g., it has 128 bits of data to output), the data deserializer 306 asserts the WB done signal 330 that causes the address buffer 304 to output the address 332 corresponding to the deserialized write data 328. The WB_done signal 330 also causes the output multiplexer 308 to output the deserialized write data 328 to the appropriate data lines of the memory array 140 specified by the selected address 332. In the case that the write data is received prior to the write command (either an externally received write command 224 following a write-activate command 222, or an internally issued write command 270 following a WR-RC command 252), the write data may be stored in the deserializer 306 until the command is issued with the corresponding address. A per bank timer circuit may control timing of issuing the internal write command 270 following the WR-RC command 252.

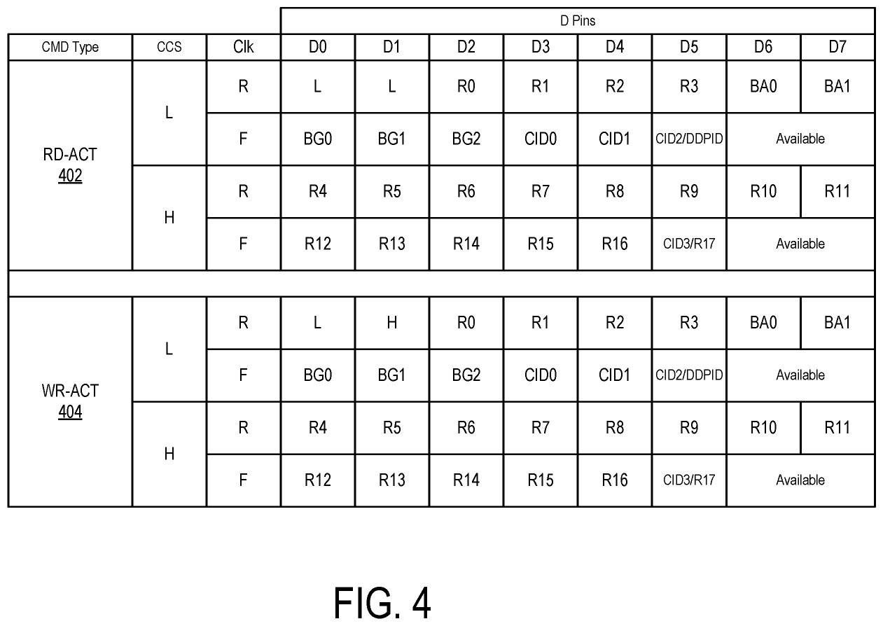

FIG. 4 illustrates an example embodiment of an encoding scheme for encoding a write-activate command 404 and a read-activate command 402. In this example, the input interface 110 has an 8-bit double data rate (DDR) D port 112 with pins D[7:0]. Bits are obtained on both rising edges (R) and falling edges (L) of the clock (CLK). Each command 402, 404 is received over two clock cycles where a CCS signal is low (L) for the first cycle and high (H) for the second cycle. In the illustrated example, DDPID represents the package identifier, CID[3:0] represents the chip identifier, BG[2:0] represents the bank group, BA[1:0] represents the bank address, and R[17:0] represents the row address. A single bit (e.g., D1 of the rising edge when CCS=L) indicates whether the command is a read-activate command 402 (D1 is low) or a write-activate command 404 (D1 is high). In this example encoding, each command 402, 404 has four available bits (in this example, received on the falling clock edges of D[7:6] in each cycle) that could be used to encode metadata, write data, or other commands.

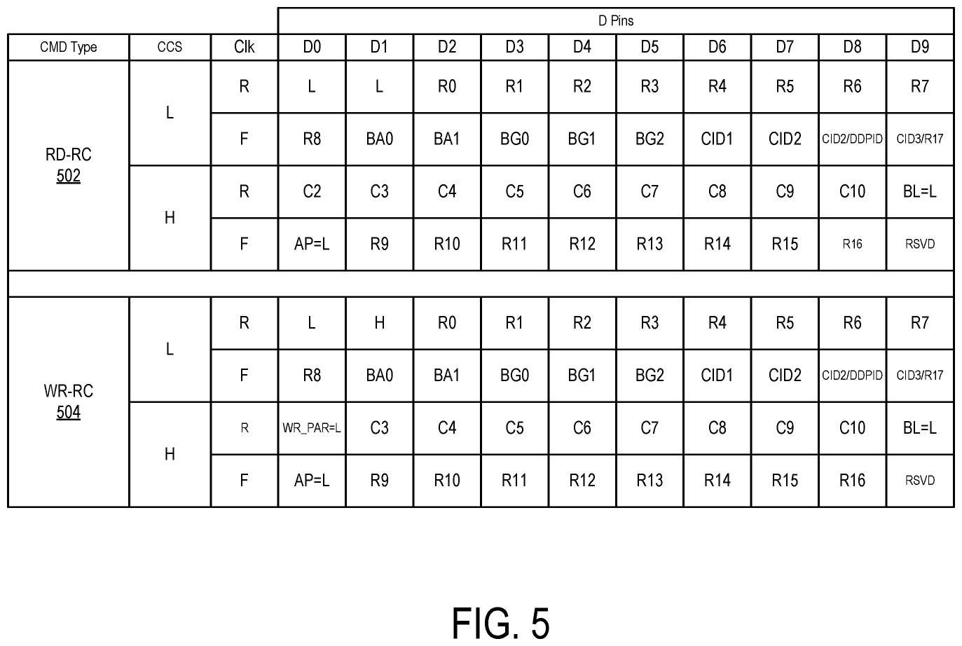

FIG. 5 illustrates an example embodiment of an encoding scheme for encoding a read-row/column (RD-RC) command 502 and a write-row/column (WR-RC) command 504. In this example, the input interface 110 has a 10-bit DDR D port 112 and each command 502, 504 is received on rising clock edges (R) and falling clock edges (F) over two clock cycles (where CCS=L for the first clock cycle and CCS=H for the second clock cycle). In this encoding, C[10:2] represents the column address, BL represents a burst length parameter, AP represents an auto precharge parameter, and WR_PAR represents a write parity parameter. One bit in each command is reserved or could be used to encode metadata, write data, or other commands.

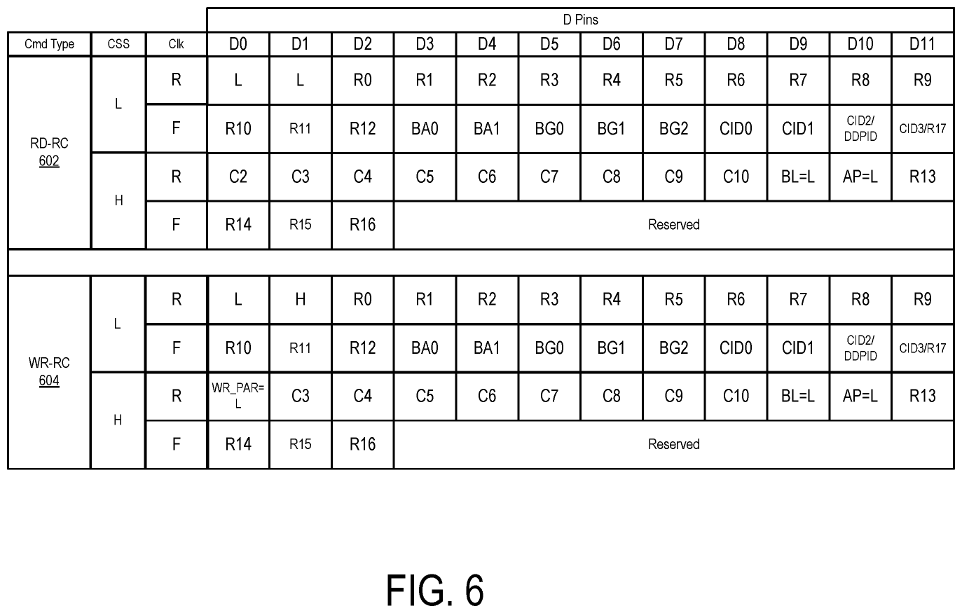

FIG. 6 illustrates an alternative example embodiment of an encoding scheme for encoding an RD-RC command 602 and a WR-RC command 604. In this example, the input interface 110 has a 12-bit DDR D port 112 and each command is obtained on rising clock edges (R) and falling clock edges (F) over two clock cycles (where CCS=L for the first clock cycle and CCS=H for the second clock cycle). In the RD-RC command 602, there are 8 bits that are reserved or could be used to encode other information. In the WR-RC command 604, there are 8 available bits that may encode a portion of the write data (e.g., 8 bits of write data) or may encode other information.

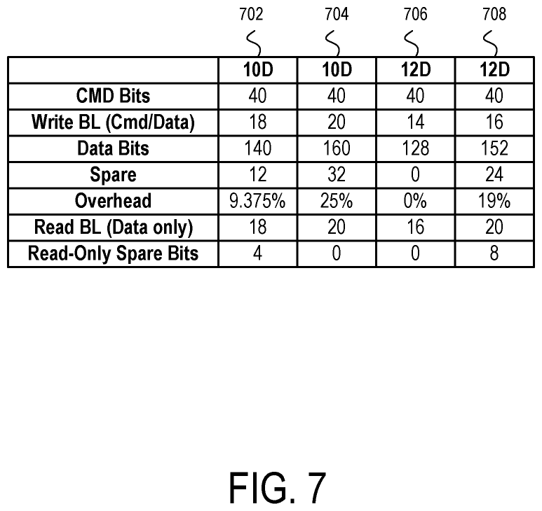

FIG. 7 is a chart illustrating examples of architectures for the memory device 100 with different widths of the D port 112 and different burst lengths (BL).

In a first configuration 702, the memory device 100 has a 10-bit D port 112 on which 40-bit commands are sent utilizing a burst length of 18. This provides 180 bits per burst of which 40 are used for the write command and up to 140 bits per burst may be used for data. For a 128-bit page, there are 12 spare bits (9.375% overhead) that could be unused, or may be used for row address select (RAS) or various metadata. For an 8-bit Q port 122 and a burst length of 18, there are 144 bits available per burst, which allows for 4 additional read-only spare bits (16 total spare bits) that may be unused or used for other data during read operations.

In a second example configuration 704, the memory device 100 has a 10-bit D port 112 on which 40-bit commands are sent utilizing a burst length of 20. This provides 200 bits per burst of which 40 are used for the write command up to 160 bits per burst may be used for data. For a 128-bit page, there are 32 spare bits (25% overhead) that could be unused or used for other data. For an 8-bit Q port 122, and a burst length of 20, there are 160 bits available per burst (same as write with no additional read-only spare bits).

In a third example configuration 706, the memory device 100 has a 12-bit D port 112 on which 40-bit commands are sent utilizing a burst length of 14. This provides for 168 bits per burst of which 40 are used for the write command and 128 data bits are used for data. Each burst fits a 128-bit page width without any spare bits or overhead. For an 8-bit Q port 122 and a burst length of 16, there are 128 bits available per burst (same as write with no additional read-only spare bits).

In a fourth example configuration 708, the memory device 100 has a 12-bit D port 112 on which 40-bit commands are sent utilizing a burst length of 16. This provides for 192 bits per burst of which 40 are used for the write command and up to 152 bits per burst may be used for data. For a 128-bit page, there are 24 spare bits (19% overhead) that could be unused or that could be unused or used for other data. For an 8-bit Q port 122 and a burst length of 20, there are 160 bits available per burst, which allows for 8 additional read-only spare bits (32 total spare bits) that may be unused or may be used for other data during read operations.

In an embodiment, the memory device 100 may have a configurable width D port 112 and/or a configurable burst length to enable the memory device 100 to dynamically change between configurations.

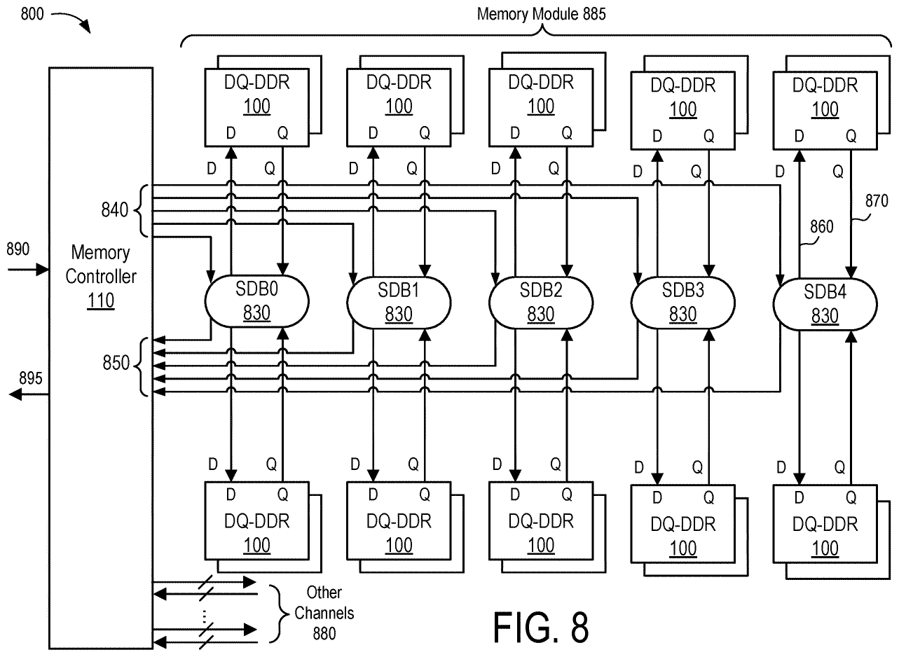

FIG. 8 is an example embodiment of a memory system 800 comprising a memory controller 810 and a memory module 885 including a plurality of serial data buffers 830 and a plurality of memory devices 100. The memory controller 810 receives a set of controller input packets via one or more memory controller input lines 890 and sends host-side input packets comprising packetized commands and write data to the serial data buffers 830 via respective downstream communication lines 840. In an embodiment, the controller input packets conform to an OpenCAPI, CXL, or other similar protocol.

The serial data buffers 130 buffer and decode the host-side input packets and send the commands and write data to the memory devices 100 via unidirectional serial input lines (D) 860. In response to read commands, the serial data buffers 830 read data from the memory devices 100 via unidirectional serial output lines (Q) 870, and transfer the read data (as buffer output packets) to the memory controller 810 via the upstream communication lines 850.

In the illustrated memory system 100, the D lines 860 and Q lines 870 are shared between a plurality of memory devices 120 coupled to the same serial data buffer 830. In this configuration, the memory devices 100 are organized into ranks where only one rank is active at a time. For example, the illustrated memory system 100 comprises a memory architecture with four ranks of five memory devices 100 (and five corresponding serial data buffers 830) in each rank (e.g., two ranks in the top row and two ranks in the bottom row). Each serial data buffer 830 is coupled to one memory device 100 from each rank over the shared D lines 860 and Q lines 870. The memory controller 110 may select the active rank based on an identifier on a chip ID (CID) field received by the memory devices 100.

In alternative configurations, a different number of memory devices 100 may be coupled to each of the serial data buffers 830 (i.e., the memory system 800 may have a different number of ranks). Furthermore, the memory system 800 may include a different number of memory devices 100 in each rank and a corresponding different number of serial data buffers 130. A single memory controller 810 may similarly control additional serial data buffers 830 and memory devices 100 (not shown) via additional channels 880.

In one embodiment, the memory controller 810, serial data buffers 830, and the memory device 100 may be implemented as separate dies within the same package. In other embodiments, they are implemented in their own respective packages. Furthermore, a memory module may comprise the serial data buffers 830 and memory devices 100 each implemented as respective integrated circuits mounted on a common printed circuit board.

In further embodiments, the memory system 800 may comprise a disaggregated memory system 800 in which the serial data buffers 830 and memory devices 100 are physically remote from the memory controller 810 and may be distributed at different locations.

Upon reading this disclosure, those of ordinary skill in the art will appreciate still alternative structural and functional designs and processes for the described embodiments, through the disclosed principles of the present disclosure. Thus, while particular embodiments and applications of the present disclosure have been illustrated and described, it is to be understood that the disclosure is not limited to the precise construction and components disclosed herein. Various modifications, changes and variations which will be apparent to those skilled in the art may be made in the arrangement, operation and details of the method and apparatus of the present disclosure herein without departing from the scope of the disclosure as defined in the appended claims.

What is claimed is:

1. A memory device comprising:
a memory array;
a command/data input port to receive commands and write data;
a read data output port to output read data; and
scheduling logic to receive a merged row/column command from the command/data input port, to initiate a row operation of the memory array responsive to the merged row/column command, and to internally initiate a column operation of the memory array following the row operation with timing controlled internally by the scheduling logic.

2. The memory device of claim 1, wherein initiating the row operation comprises activating a row of the memory array.

3. The memory device of claim 1, wherein initiating the column operation comprises:
issuing a write command to the memory array; and
following the write command, sending the write data to the memory array.

4. The memory device of claim 3, wherein the scheduling logic is configured to receive at least a first portion of the write data from the command/data input port after the scheduling logic initiates the row operation and before or during issuance of the write command, to store the first portion of the write data to a buffer, and to issue the first portion of the write data to the memory array from the buffer following the write command.

5. The memory device of claim 4, wherein the scheduling logic is configured to receive at least a second portion of the write data from the command/data input port after the scheduling logic sends the write command, and to issue the second portion of the write data to the memory array.

6. The memory device of claim 1, wherein initiating the column operation comprises:
issuing a read command to the memory array.

7. The memory device of claim 6, wherein the scheduling logic is configured to receive the read data from the memory array following the read command and output the read data to the read data output port.

8. The memory device of claim 1, wherein the memory array comprises a dynamic random-access memory (DRAM) array.

9. A memory module comprising:
a plurality of memory devices, wherein each of the plurality of memory devices comprises:
a memory array;
a command/data input port to receive commands and write data;
a read data output port to output read data; and
scheduling logic to receive a merged row/column command from the command/data input port, to initiate a row operation of the memory array responsive to the merged row/column command, and to initiate a column operation of the memory array following the row operation with timing controlled internally by the scheduling logic.

10. The memory module of claim 9, wherein initiating the row operation comprises activating a row of the memory array.

11. The memory module of claim 9, wherein initiating the column operation comprises:
issuing a write command to the memory array; and
following the write command, sending the write data to the memory array.

12. The memory module of claim 11, wherein the scheduling logic is configured to receive at least a first portion of the write data from the command/data input port after the scheduling logic initiates the row operation and before the scheduling logic sends the write command, to store the first portion of the write data to a buffer, and to issue the first portion of the write data to the memory array from the buffer following the write command.

13. The memory module of claim 12, wherein the scheduling logic is configured to receive at least a second portion of the write data from the command/data input port after the scheduling logic sends the write command, and to issue the second portion of the write data to the memory array.

14. The memory module of claim 9, wherein initiating the column operation comprises:
issuing a read command to the memory array.

15. The memory module of claim 14, wherein the scheduling logic is configured to receive the read data from the memory array following the read command and output the read data to the read data output port.

16. The memory module of claim 9, wherein the memory array comprises a dynamic random-access memory (DRAM) array.

17. A memory device comprising:
a memory array;
a command/data input port to receive commands and write data;
a read data output port to output read data; and
scheduling logic to receive an activate command from the command/data input port that includes one or more control bits associating the activate command with a write operation, to receive a write command following the activate command, and to initiate the write operation the memory array following the write command.

18. The memory device of claim 17, wherein the scheduling logic is configured to receive at least a portion of the write data from the command/data input port after the scheduling logic receives the activate command and before the scheduling logic receives the write command, and wherein the scheduling logic is configured to store the write data to a buffer and to issue the write data to the memory array from the buffer after receiving the write command.

19. The memory device of claim 17, wherein the scheduling logic is further configured to receive a read command from the command/data input port, initiate a read operation from the memory array, and output the read data via the read data output port.

20. The memory device of claim 17, wherein the memory array comprises a dynamic random-access memory (DRAM) array.
